(19) United States
(12) Patent Application Publication
(10) Pub. No.: US 2026/0164783 A1
(43) Pub. Date: Jun. 11, 2026

(54) NANOSHEET SEMICONDUCTOR DEVICE WITH DIELECTRIC WALL AND METHOD FOR MANUFACTURING THE SAME

(71) Applicant: Taiwan Semiconductor Manufacturing Company, Ltd., Hsinchu (TW)

(72) Inventors: Kuan-Ting PAN, Hsinchu (TW); Yi-Ruei JHAN, Hsinchu (TW); Wei Ting WANG, Hsinchu (TW); Kuo-Cheng CHIANG, Hsinchu (TW); Chih-Hao WANG, Hsinchu (TW)

(73) Assignee: Taiwan Semiconductor Manufacturing Company, Ltd., Hsinchu (TW)

(21) Appl. No.: 18/975,493

(22) Filed: Dec. 10, 2024

(51) Int. Cl. H10D 84/85; H10D 84/01

(52) U.S. Cl. CPC H10D 84/851; H10D 84/0167; H10D 84/017; H10D 84/0186; H10D 84/0188

(57) ABSTRACT

A method for manufacturing a semiconductor device includes: forming first stacks on a semiconductor substrate, each of the first stacks including dielectric interposers and channel features that are alternately stacked on the semiconductor substrate; forming a dummy poly gate on the semiconductor substrate, the dummy poly gate including a dummy gate dielectric covering the first stacks and a dummy gate electrode covering the dummy gate dielectric; removing a portion of the dummy gate electrode and a portion of the dummy gate dielectric, so as to form a wall recess; and forming a dielectric wall in the wall recess.

### BACKGROUND

With the dramatic advancement of the semiconductor manufacturing technology, a semiconductor integrated circuit (IC) chip can be scaled down with an increased device functional density (i.e., the number of electrical devices per chip area). For example, in a semiconductor IC chip with three-dimensional transistors, FEOL (front-end-of-line) metal gate (MG) structure is being cut to obtain a plurality of metal gate portions, and each of the metal gate portions can be used in an individual transistor. Nevertheless, in order to further enhance the power efficiency of a semiconductor IC chip, improvement of the electrical characteristics thereof is required, such as lowering chip capacitance for reducing resistance-capacitance (RC) time delay.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are flow diagrams illustrating a method for manufacturing a semiconductor device in accordance with some embodiments.

FIGS. 2 to 23 are schematic views illustrating some stages of the method as depicted in FIGS. 1A and 1B in accordance with some embodiments.

FIG. 24 is a schematic view illustrating a partially enlarged portion of a semiconductor device in accordance with some embodiments.

FIG. 25 is a schematic view illustrating a semiconductor device in accordance with some alternative embodiments.

FIG. 26 is a layout diagram illustrating some critical layout dimensions of a semiconductor device in accordance with some embodiments.

FIG. 27 is a layout diagram illustrating some critical layout dimensions of a semiconductor device in accordance with some alternative embodiments.

FIG. 28 is a layout diagram illustrating some critical layout dimensions of a semiconductor device in accordance with some further alternative embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “upper,” “lower,” “lowermost,” “uppermost,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±20%, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain region(s)” may refer to a source or a drain, individually or collectively dependent upon the context.

Nowadays, nanosheet semiconductor devices (e.g., nanosheet field-effect transistors (FETs)) are applied in various fields, such as consumer electrical products. In order to meet various application needs, the semiconductor industry strives to improve device performance of the nanosheet semiconductor devices. However, improvement of the device performance of the nanosheet semiconductor devices faces some challenges. For example, there is a restriction on reduction of a spacing between two oxide-definition regions in a nanosheet semiconductor device because a certain size of metal gate endcap portions (i.e., portions of a metal gate structure defined between a plurality of channel features and an isolation portion that is disposed in the metal gate structure) is required for meeting requirements of device performance (e.g., a threshold voltage (Vₜₕ) or the like) of the nanosheet semiconductor device. For example, the isolation portion is formed to cut the metal gate structure, and formation of the isolation portion may be affected by certain fabrication process variations (e.g., overlay shift and critical dimension variation in photolithography process or the like), resulting in a reduction of size of the metal gate endcap portions, and further affecting the Vₜₕ of the nanosheet semiconductor device. In addition, the nanosheet semiconductor devices still have a resistance-capacitance (RC) time delay issue to be solved. Therefore, in order to improve device performance of the nanosheet semiconductor devices, these challenges need to be overcome.

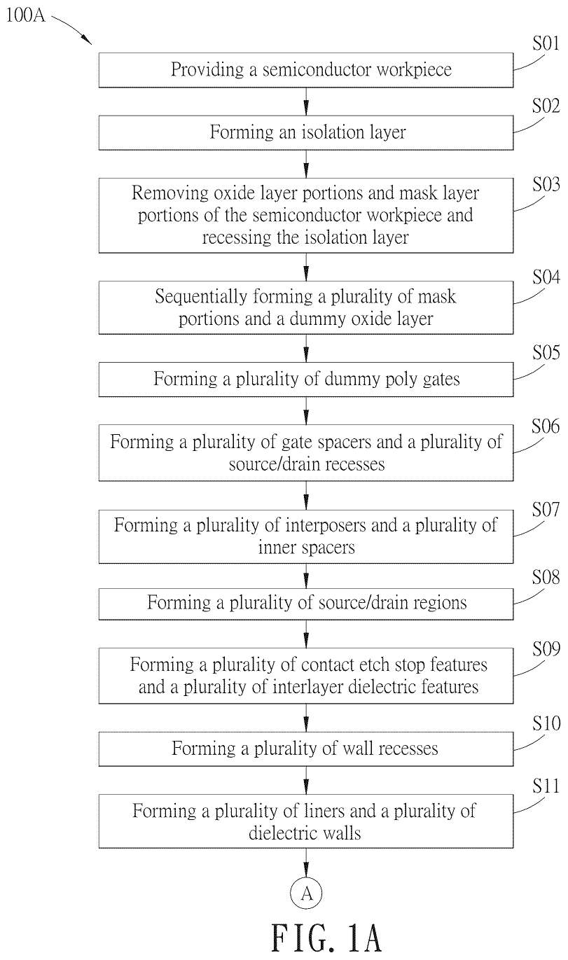

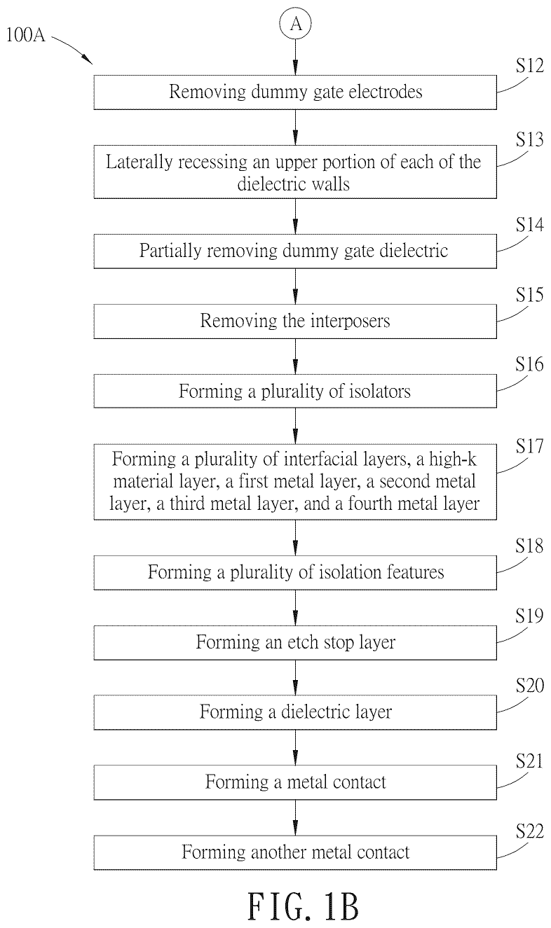

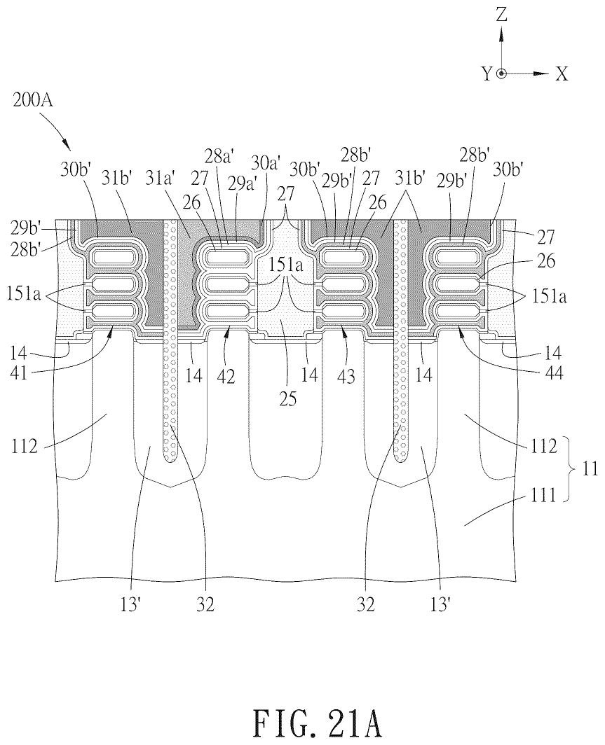

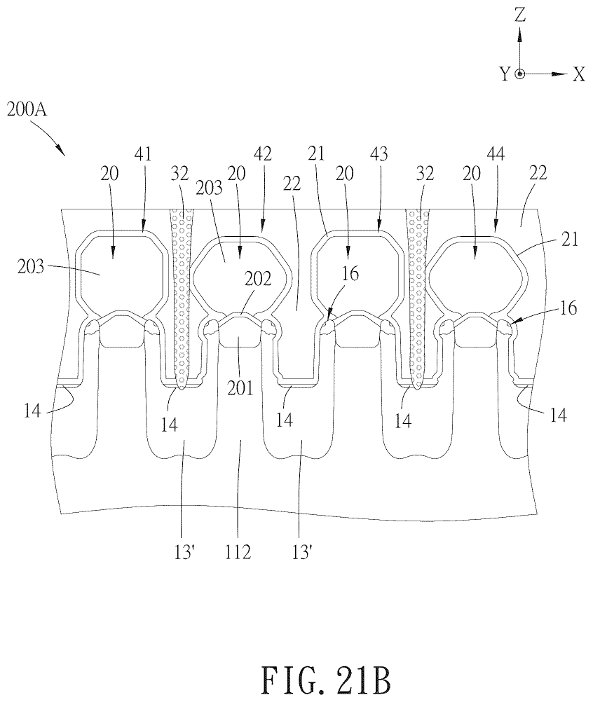

The present disclosure is directed to a semiconductor device and a method for manufacturing the same. FIGS. 1A and 1B are flow diagrams illustrating a method 100A for manufacturing a semiconductor device 200A shown in FIGS. 21A, 21B, 22 and 23 in accordance with some embodiments. FIGS. 2 to 20 illustrate schematic views of some intermediate stages of the method 100A. Some portions may be omitted in FIGS. 2 to 23 for the sake of brevity. Additional steps can be provided before, after or during the method 100A, and some of the steps described herein may be replaced by other steps or be eliminated.

Referring to FIG. 1A and the example illustrated in FIG. 2, the method 100A begins at step S01, where a semiconductor base structure 1 is provided. The semiconductor base structure 1 includes a semiconductor substrate 11 and a plurality of fin structures 12.

The semiconductor substrate 11 may include, for example, but are not limited to, an elemental semiconductor or a compound semiconductor. The elemental semiconductor includes a single species of atoms, such as silicon or germanium from column XIV of the periodic table, and may be a crystalline structure, a polycrystalline structure, or an amorphous structure. Other suitable materials for the elemental semiconductor are within the contemplated scope of the present disclosure. The compound semiconductor includes two or more elements, and examples thereof may include, but are not limited to, silicon carbide, gallium arsenide, gallium phosphide, indium phosphide, indium arsenide, indium antimonide, silicon germanium, gallium arsenide phosphide, aluminum indium arsenide, aluminum gallium arsenide, gallium indium arsenide, gallium indium phosphide, and gallium indium arsenide phosphide. Other suitable materials for the compound semiconductor are within the contemplated scope of the present disclosure. The compound semiconductor may have a gradient feature in which the compositional ratio thereof changes from one location to another location in the compound semiconductor. The compound semiconductor may be formed over a silicon substrate and may be strained. In some embodiments, the semiconductor substrate 11 may include a multilayer compound semiconductor structure. In some embodiments, the semiconductor substrate 11 may include a base portion 111 and a plurality of fin portions 112 that are disposed on the base portion 111 in a Z direction normal to a lower surface of the semiconductor substrate 11 and that are spaced apart from each other by trenches in an X direction transverse to the Z direction. In some embodiments, the X direction is perpendicular to the Z direction.

The fin structures 12 are respectively disposed on the fin portions 112 of the semiconductor substrate 11. Each of the fin structures 12 includes a nanosheet stack, an oxide layer portion 123′, and a mask layer portion 124′ that are sequentially disposed on a corresponding one of the fin portions 112 of the semiconductor substrate 11. The nanosheet stack includes a plurality of sacrificial layer portions 121′ and a plurality of channel layer portions 122′ which are alternately stacked over one another. The sacrificial layer portions 121′ may include a first semiconductor material (for example, but not limited to, silicon germanium). The channel layer portions 122′ may include a second semiconductor material (for example, but not limited to, silicon) different from the first semiconductor material. The oxide layer portion 123′ is disposed on the nanosheet stack opposite to the semiconductor substrate 11, and may include, for example, but not limited to, silicon oxide. The mask layer portion 124′ is disposed on the oxide layer portion 123′ opposite to the nanosheet stack, and may be made of a nitride-based material (for example, but not limited to, silicon nitride). Other suitable materials for each of the sacrificial layer portions 121′, the channel layer portions 122′, the oxide layer portion 123′, and the mask layer portion 124′ are within the contemplated scope of the present disclosure.

In some embodiments, the semiconductor base structure 1 is obtained by sequentially forming a semiconductor stack (not shown), an oxide layer (not shown) and a mask layer (not shown) over the semiconductor substrate 11, followed by conducting a photolithography process to pattern the semiconductor stack, the oxide layer and the mask layer. In some embodiments, the semiconductor stack may include a plurality of sacrificial layers (not shown) and a plurality of channel layers (not shown) which are alternately stacked on the semiconductor substrate 11. In some embodiments, the sacrificial layers and the channel layers may be formed by a suitable deposition process, for example, but not limited to, chemical vapor deposition (CVD) (e.g., ultra-high vacuum CVD (UHV-CVD)) or other suitable deposition processes. In some alternative embodiments, the sacrificial layers and the channel layers may be formed by a suitable epitaxial process, for example, but not limited to, molecular beam epitaxy (MBE) or other suitable epitaxial processes. The oxide layer may be formed by a suitable deposition process, for example, but not limited to, CVD, atomic layer deposition (ALD), or other suitable deposition processes. The mask layer may be formed by a suitable deposition process, for example, but not limited to, CVD (e.g., plasma-enhanced CVD (PECVD)), ALD (e.g., plasma-enhanced ALD (PEALD)), or other suitable deposition processes. After the photolithography process, the trenches are formed to penetrate through the mask layer, the oxide layer and the semiconductor stack, and to terminate at the base portion 111 of the semiconductor substrate 111, so as to form the sacrificial layers into the sacrificial layer portions 121′, to form the channel layers into the channel layer portions 122′, to form the oxide layer into the oxide layer portions 123′, and to form the mask layer into the mask layer portions 124′.

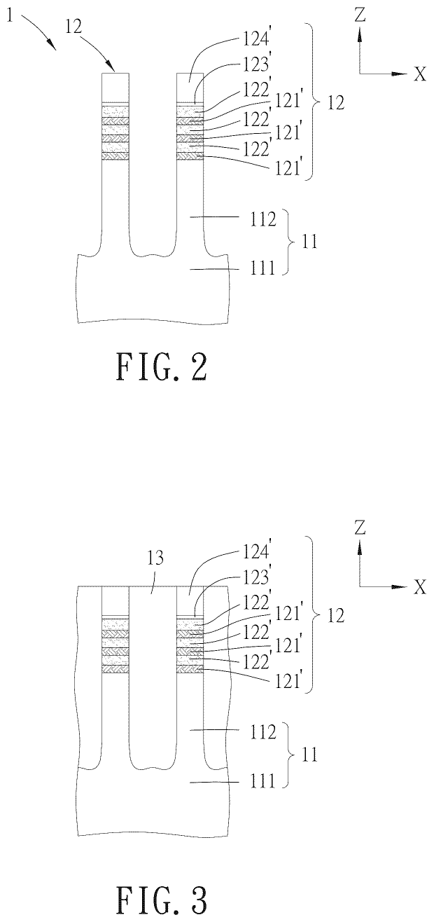

Referring to FIG. 1A and the example illustrated in FIG. 3, the method 100A then proceeds to step S02, where an isolation layer 13 is formed on the structure shown in FIG. 2. The isolation layer 13 may be made of a dielectric oxide-based material (for example, but not limited to, silicon oxide), a dielectric nitride-based material (for example, but not limited to, silicon nitride), or a combination thereof. Other suitable materials for the isolation layer 13 are within the contemplated scope of the present disclosure. The isolation layer 13 may be formed by a suitable deposition process, for example, but not limited to, CVD, physical vapor deposition (PVD), or other suitable deposition processes. In this step, after formation of the isolation layer 13, a planarization process (e.g., a chemical mechanical planarization (CMP) process or other suitable planarization processes) may be performed to remove an excess portion of the isolation layer 13.

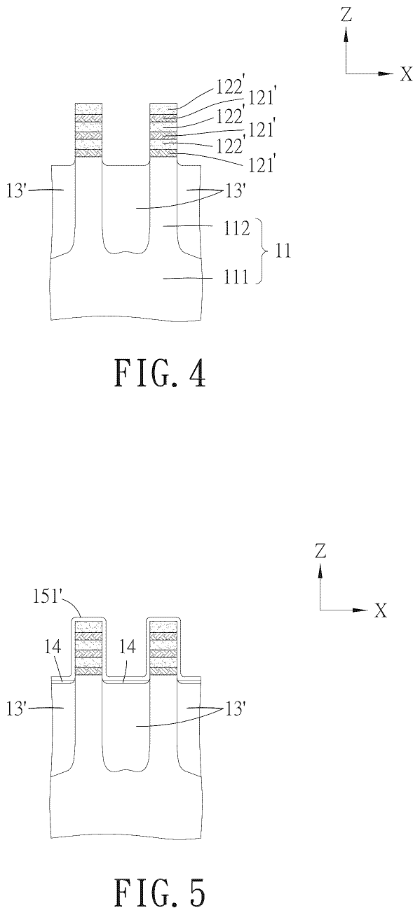

Referring to FIG. 1A and the example illustrated in FIG. 4, the method 100A then proceeds to step S03, where the oxide layer portions 123′ and the mask layer portions 124′ (see FIG. 3) are removed and the isolation layer 13 (see FIG. 3) is recessed by a suitable etching process (for example, but not limited to, a dry etching process, a wet etching process or a combination thereof), so as to form a plurality of isolation layer portions 13′. Each of the isolation layer portions 13′ is disposed on the base portion 111 of the semiconductor substrate 11 and in a corresponding one of the trenches. Two adjacent ones of the isolation layer portions 13′ are located at two opposite sides (e.g., opposite to each other in the X direction) of a corresponding one of the fin portions 112 of the semiconductor substrate 11, so as to separate and isolate the nanosheet stacks from each other. Each of the nanosheet stacks includes the sacrificial layer portions 121′ and the channel layer portions 122′ which are alternately stacked over one another. In some embodiments, each of the isolation layer portions 13′ may be a portion of a shallow trench isolation (STI), a deep trench isolation (DTI), or other suitable structures.

Referring to FIG. 1A and the example illustrated in FIG. 5, the method 100A then proceeds to step S04, where a plurality of mask portions 14 and a dummy oxide layer 151′ are sequentially formed on the structure shown in FIG. 4. In some embodiments, the mask portions 14 may be formed on the isolation layer portions 13′, respectively by: (i) forming a mask material layer to cover the isolation layer portions 13′ and the nanosheet stacks by a suitable deposition process (for example, but not limited to, CVD, PVD, or other suitable deposition processes), in which the mask material layer includes a plurality of horizontal layer portions respectively disposed on the isolation layer portions 13′ and upper surfaces of the nanosheet stacks and a plurality of vertical layer portions laterally covering the nanosheet stacks and having thicknesses less than those of the horizontal layer portions; (ii) forming a dielectric layer (for example, but not limited to, a bottom anti-reflective coating (BARC) layer) on the mask material layer to fill recesses among the nanosheet stacks; (iii) etching back the dielectric layer to expose the horizontal layer portions disposed on the upper surfaces of the nanosheet stacks; (iv) removing the horizontal layer portions disposed on the upper surfaces of the nanosheet stacks by, for example, but not limited to, a suitable selective etching process; (v) removing the dielectric layer by, for example, but not limited to, a suitable etching process; and (vi) removing the vertical layer portions and upper parts of the horizontal layer portions disposed on the isolation layer portions 13′, so that remaining parts of the horizontal layer portions disposed on the isolation layer portions 13′ are formed into the mask portions 14. In some embodiments, the mask portions 14 (or the mask material layer) may include, for example, but not limited to, silicon nitride, silicon oxynitride, silicon carbonitride, silicon oxycarbonitride, or the like. Other suitable materials for the mask portions 14 (or the mask material layer) are within the contemplated scope of the present disclosure. Thereafter, the dummy oxide layer 151′ is conformally formed to cover the mask portions 14 and the nanosheet stacks. In some embodiments, the dummy oxide layer 151′ may include, for example, but not limited to, silicon oxide. Other suitable materials for the dummy oxide layer 151′ are within the contemplated scope of the present disclosure. In some embodiments, the dummy oxide layer 151′ may be formed by a suitable deposition process, for example, but not limited to, CVD, ALD, or other suitable deposition processes.

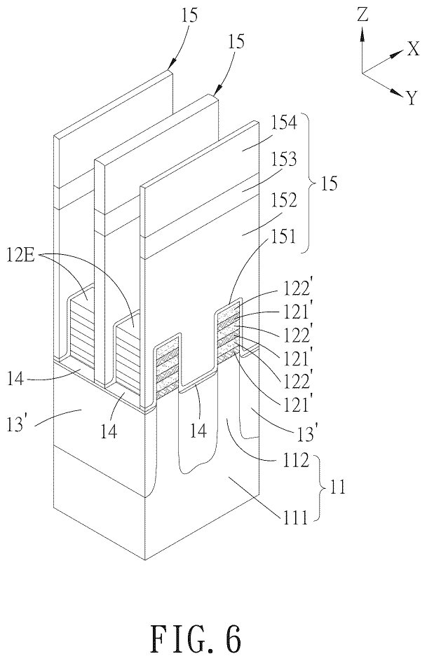

Referring to FIG. 1A and the example illustrated in FIG. 6, the method 100A then proceeds to step S05, where a plurality of dummy poly gates 15 are formed. Each of the dummy poly gates 15 may include a dummy gate dielectric 151, a dummy gate electrode 152, a mask portion 153, and a mask portion 154. In some embodiments, step S05 may be performed by depositing a dummy layer for forming the dummy gate electrode 152 on the structure shown in FIG. 5, conducting a planarization process (for example, but not limited to, the CMP process) to remove an excess portion of the dummy layer, sequentially depositing a mask material layer for forming the mask portion 153 and a mask material layer for forming the mask portion 154 on the planarized dummy layer, and patterning the two mask material layers, the planarized dummy layer, and the dummy oxide layer 151′, so that the dummy poly gates 15 are formed. The dummy poly gates 15 are spaced apart from each other along a Y direction transverse to the X and Z directions. In some embodiments, the X, Y, and Z directions are perpendicular to one another. In some embodiments, the dummy gate electrode 152 (or the dummy layer) may include, for example, but not limited to, polysilicon. Other suitable materials for the dummy gate electrode 152 (or the dummy layer) are within the contemplated scope of the present disclosure. In each of the dummy poly gates 15, the mask portion 153 is disposed on the dummy gate electrode 152 opposite to the dummy gate dielectric 151. The mask portion 153 may include, for example, but not limited to, silicon nitride. Other suitable materials for the mask portion 153 are within the contemplated scope of the present disclosure. In each of the dummy poly gates 15, the mask portion 154 is disposed on the mask portion 153 opposite to the dummy gate electrode 152. The mask portion 154 may include, for example, but not limited to, silicon oxide. Other suitable materials for the mask portion 154 are within the contemplated scope of the present disclosure. In some embodiments, each of the dummy layer for forming the dummy gate electrode 152 and the two mask material layers for forming the mask portions 153, 154 may be deposited by a suitable deposition process, for example, but not limited to, CVD, ALD, PVD, or other suitable deposition processes. After this step, a plurality of exposed regions 12E are formed. Each of the exposed regions 12E is located between corresponding two adjacent ones of the dummy poly gates 15.

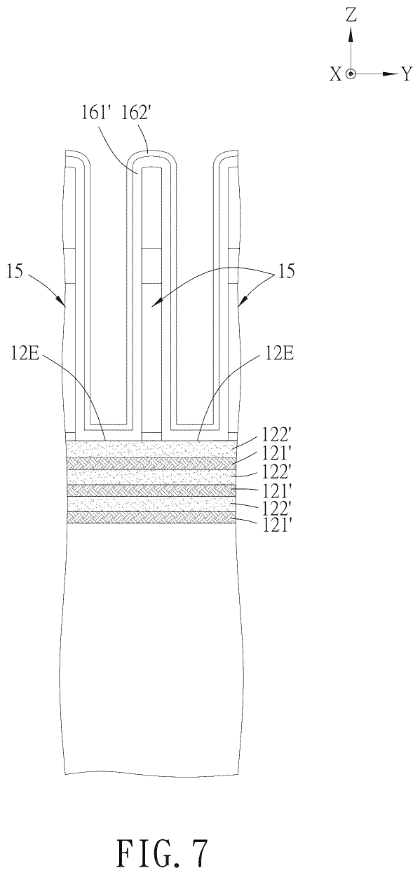

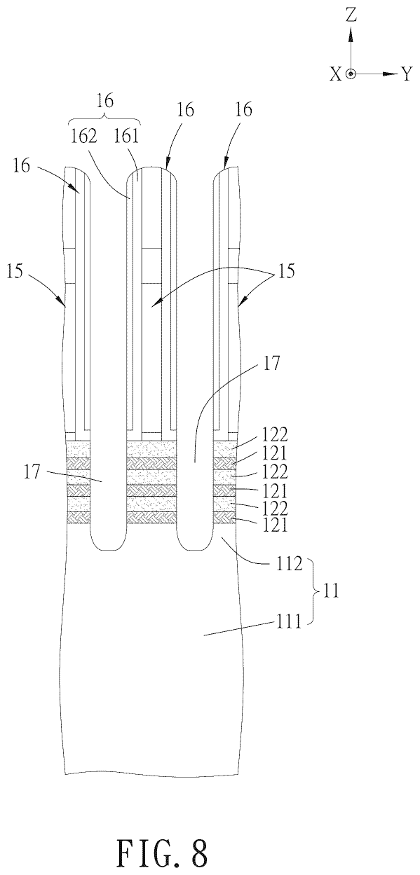

Referring to FIG. 1A and the examples illustrated in FIGS. 7 and 8, the method 100A then proceeds to step S06, where a plurality of gate spacers 16 are formed on the structure shown in FIG. 6, followed by recessing the exposed regions 12E (see FIG. 6), to form a plurality of source/drain recesses 17. Step S06 may include sub-steps (a1) and (a2).

In sub-step (a1), a spacer material layer 161′ and a spacer material layer 162′ for forming the gate spacers 16 are sequentially deposited on the dummy poly gates 15 and the exposed regions 12E, followed by conducting an anisotropic dry etching process until portions of the spacer material layers 161′, 162′, which are formed on the exposed regions 12E and an upper surface of each of the dummy poly gates 15, are removed such that remaining portions of the spacer material layers 161′, 162′ serve as the gate spacers 16. In some embodiments, each of the spacer material layers 161′, 162′ may be formed by a suitable deposition process, for example, but not limited to, CVD, ALD, or other suitable deposition processes. Each of the spacer material layers 161′, 162′ may include, for example, but not limited to, silicon oxide, silicon nitride, silicon oxynitride, silicon carbonitride, silicon oxycarbonitride, or low dielectric constant (k) materials. Other suitable materials for the gate spacers 16 are within the contemplated scope of the present disclosure. In some embodiments, the spacer material layers 161′, 162′ may be different from each other. Each pair of the gate spacers 16 is respectively formed at two opposite sides of a corresponding one of the dummy poly gates 15 in the Y direction. Each of the gate spacers 16 is formed as a two-layered structure, and includes an outer spacer part 162 and an inner spacer part 161 disposed between a corresponding one of the dummy poly gates 15 and the outer spacer part 162. In some embodiments, each of the gate spacers 16 may be formed as a single layer structure.

In sub-step (a2), the exposed regions 12E (see FIG. 6 or FIG. 7) are recessed by a suitable etching process, for example, but not limited to, an anisotropic dry etching process, so as to form the source/drain recesses 17 that are spaced apart from each other in the Y direction. After sub-step (a 2), the sacrificial layer portions 121′ and the channel layer portions 122′ (see FIG. 6 or FIG. 7) are respectively patterned into sacrificial features 121 and channel features 122 which are alternately stacked over one another.

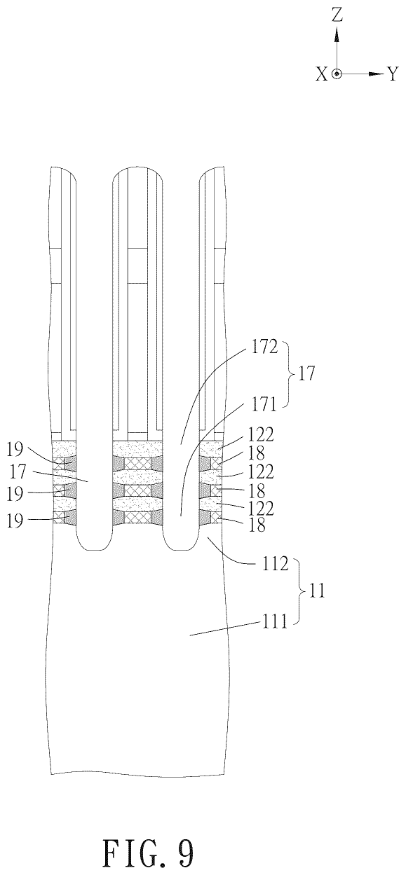

Referring to FIG. 1A and the example illustrated in FIG. 9, the method 100A then proceeds to step S07, where a plurality of interposers 18 and a plurality of inner spacers 19 are formed. Step S07 may include sub-steps (b1), (b2), and (b3).

In sub-step (b1), the sacrificial features 121 of the structure shown in FIG. 8 are removed to form a plurality of spaces (not shown). In some embodiments, the sacrificial features 121 may be removed by an isotropic etching process (for example, but not limited to, a wet etching process) or other suitable etching processes. Each of lowermost ones of the spaces is located between a corresponding one of the channel features 122 and a corresponding one of the fin portions 112 of the semiconductor substrate 11, and each of remaining ones of the spaces is located between corresponding two adjacent ones of the channel features 122.

In sub-step (b2), a dielectric oxide-based material layer (for example, but not limited to, a silicon oxide layer) is formed on the structure obtained after sub-step (b1) to fill the spaces, followed by conducting an isotropic etching process to remove an excess portion of the dielectric oxide-based material layer, so as to form the interposers 18 and a plurality of lateral recesses (not shown). The lateral recesses are in spatial communication with the source/drain recesses 17, and each pair of the lateral recesses are located at two opposite sides of a corresponding one of the interposers 18. In some embodiments, the dielectric oxide-based material layer may be formed by a suitable deposition process, for example, but not limited to, CVD or ALD. Other suitable deposition processes for forming the dielectric oxide-based material layer are within the contemplated scope of the present disclosure. In some embodiments, the isotropic etching process may be an isotropic wet etching process, an isotropic dry etching process, or a combination thereof. Each of lowermost ones of the interposers 18 is located between a corresponding one of the channel features 122 and a corresponding one of the fin portions 112 of the semiconductor substrate 11, and each of remaining ones of the interposers 18 is located between corresponding two adjacent ones of the channel features 122.

In sub-step (b3), a spacer material layer (not shown) is formed on the structure obtained after sub-step (b2) to fill the lateral recesses by a suitable deposition process, (for example, but not limited to, CVD, ALD, or other suitable deposition processes), followed by removing an excess portion of the spacer material layer by a suitable etching process, for example, but not limited to, a dry etching process, a wet etching process, or a combination thereof, thereby obtaining the inner spacers 19. In some embodiments, the spacer material layer for forming the inner spacers 19 may include, for example, but not limited to, silicon oxide, silicon nitride, silicon oxynitride, silicon carbonitride, silicon oxycarbonitride, silicon oxycarbide, silicon carbide, or combinations thereof. Other suitable materials for forming the spacer material layer are within the contemplated scope of the present disclosure. After sub-step (b3), remaining portions of the spacer material layer may be referred to as the inner spacers 19. In some embodiments, each pair of the inner spacers 19 laterally covers two opposite sides of a corresponding one of the interposers 18.

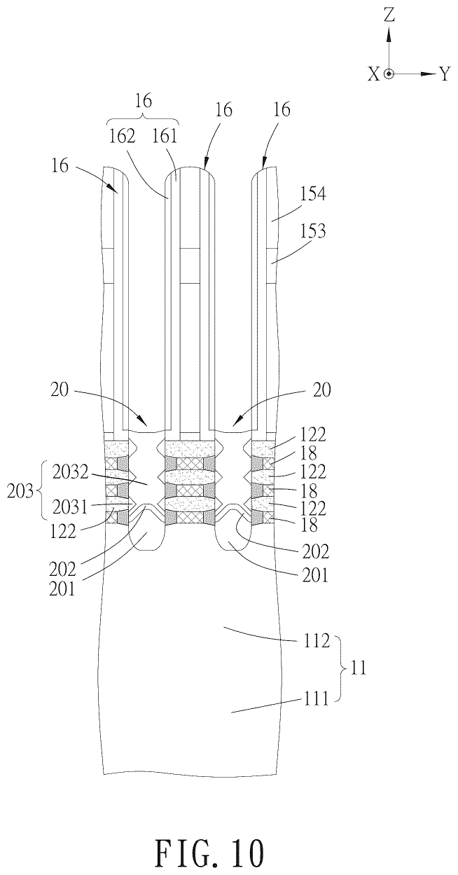

Referring to FIG. 1A and the example illustrated in FIG. 10, the method 100A then proceeds to step S08, where a plurality of source/drain regions 20 are formed. Step S08 may include sub-steps (c1), (c2), and (c3).

In sub-step (c1), a plurality of first layers 201 are respectively formed in lower recess portions 171 of the source/drain recesses 17 (see FIG. 9). The first layers 201 may be made of a semiconductor material, for example, but not limited to, silicon. Other suitable semiconductor materials for forming the first layers 201 are within the contemplated scope of the present disclosure. The first layers 201 may be formed by, for example, but not limited to, a deposition process (for example, but not limited to, CVD), an epitaxial growth process (for example, but not limited to, MBE), an epitaxial deposition/partial etch process (for example, but not limited to, a cyclic deposition-etch (CDE) process), or a selective epitaxial growth (SEG) process. Other suitable processes for forming the first layers 201 are within the contemplated scope of the present disclosure.

In sub-step (c2), a plurality of second layers 202 are respectively formed on the first layers 201 in the source/drain recesses 17. Sub-step (c2) may involve depositing a dielectric material layer for forming the second layers 202 in the source/drain recesses 17 and on the other structures by a suitable deposition process, for example, but not limited to, CVD, ALD, or other suitable deposition processes, and then removing excess portions of the dielectric material layer for forming the second layers 202 by a suitable etching process, for example, but not limited to, a wet etching process, a dry etching process, other suitable etching processes, or combinations thereof, such that remaining portions of the dielectric material layer serve as the second layers 202 which are respectively formed on the first layers 201 in the source/drain recesses 17. The dielectric material layer for forming the second layers 202 may include silicon oxide or silicon nitride. Other suitable dielectric materials for the second layers 202 are within the contemplated scope of the present disclosure. In some embodiments, the second layers 202 may be referred to as bottom dielectric isolations (BDIs).

In sub-step (c3), a plurality of source/drain features 203 are respectively formed on the second layers 202 in upper recess portions 172 of the source/drain recesses 17 (see FIG. 9). In some embodiments, each of the source/drain features 203 includes a plurality of outer regions 2031 and a major region 2032, and each of the outer regions 2031 is disposed between a corresponding one of the channel features 122 and the major region 2032. Sub-step (c3) may be performed by sequentially forming the outer regions 2031 and the major region 2032 in the upper recess portions 172 of the source/drain recesses 17 using an epitaxial growth technique. In some embodiments, the outer regions 2031 may serve as seeding layers for forming the major region 2032. In some embodiments in which the channel features 122 are made of silicon, the outer regions 2031 and the major region 2032 may be made of silicon. In some alternative embodiments, the outer regions 2031 may be made of silicon and the major region 2032 may be made of silicon germanium. The source/drain regions 20 are formed accordingly, and each of the source/drain regions 20 includes a corresponding one of the first layers 201, a corresponding one of the second layers 202, and a corresponding one of the source/drain features 203.

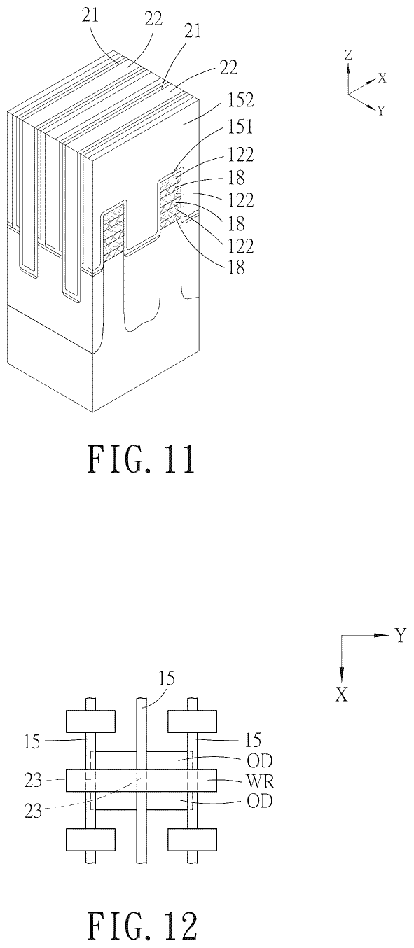

Referring to FIG. 1A and the example illustrated in FIG. 11, the method 100A then proceeds to step S09, where a plurality of contact etch stop features 21 and a plurality of interlayer dielectric (ILD) features 22 are respectively formed on the source/drain features 203. Step 09 may include sub-steps (d1) and (d2).

In sub-step (d1), a contact etch stop layer (not shown) for forming the contact etch stop features 21 and a dielectric material layer (not shown) for forming the ILD features 22 are sequentially formed over the structure shown in FIG. 10 by a blanket deposition process, for example, but not limited to, CVD or molecular layer deposition (MLD). The contact etch stop layer for forming the contact etch stop features 21 may include, for example, but not limited to, silicon nitride, silicon oxynitride, silicon carbonitride, silicon oxycarbonitride, other suitable contact etch stop materials, or combinations thereof. The dielectric material layer for forming the ILD features 22 may include, for example, but not limited to, silicon oxide, silicon nitride, silicon oxynitride, other suitable dielectric materials, or combinations thereof. Other suitable materials for forming the contact etch stop features 21 and the ILD features 22 are within the contemplated scope of the present disclosure. In some embodiments, the material for forming the contact etch stop features 21 is different from that for forming the ILD features 22.

In sub-step (d2), a planarization process (e.g., the CMP process or other suitable planarization processes) is performed to remove excess portion of the contact etch stop layer and excess portion of the dielectric material layer, so as to obtain the contact etch stop features 21 and the ILD features 22. In this sub-step, the mask portion 154 and the mask portion 153 of each of the dummy poly gates 15 may also be removed.

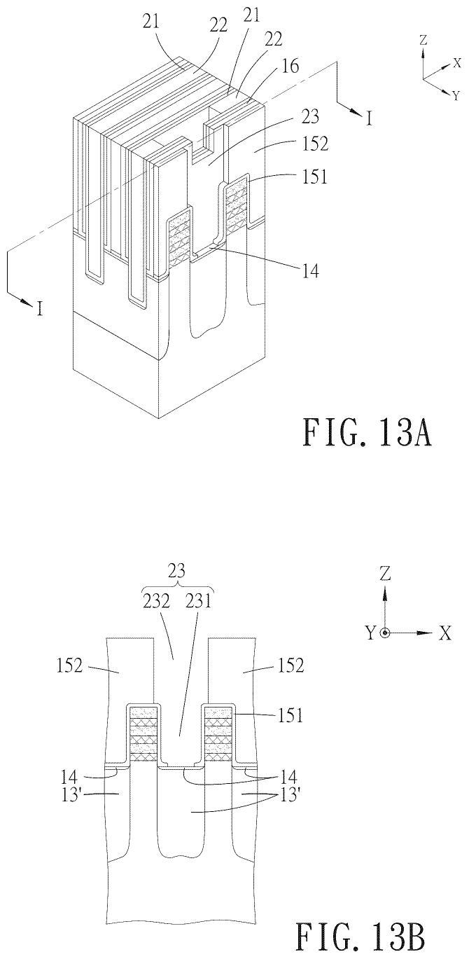

Referring to FIG. 1A and the example illustrated in FIGS. 12, 13A and 13B, the method 100A then proceeds to step S10, where a plurality of wall recesses 23 are formed. FIG. 12 is a layout diagram which illustrates a photomask pattern for forming the wall recesses 23 and a plurality of oxide-definition (OD) regions, at which the source/drain regions 20 (see FIG. 10) are formed. A wall recces (WR) definition region is formed between corresponding two adjacent ones of the oxide-definition (OD) regions. FIG. 13B illustrates a cross-sectional view taken along line I-I of FIG. 13A. Step S10 may include sub-step (i) forming a mask layer, which has a pattern defined by the photomask pattern shown in FIG. 12, on the structure shown in FIG. 11, and sub-step (ii) removing portions of the dummy gate electrode 152 and portions of the dummy gate dielectric 151 of each of the dummy poly gates 15 by a photolithography process, which may include at least one etching process (for example, but not limited to, a plasma dry etching process), so as to form the wall recesses 23. Only one of the wall recesses 23 is shown in FIGS. 13A and 13B. In some embodiments, the mask layer may include polysilicon, silicon nitride, silicon oxide, or combinations thereof. Other suitable materials for the mask layer are within the contemplated scope of the present disclosure. In some embodiments, each of the wall recesses 23 may be divided into a lower recess portion 231 that is defined by the dummy gate dielectric 151 and a corresponding one of the mask portions 14, and an upper recess portion 232 that is in spatial communication with the lower recess portion 231. As shown in FIG. 13A, the gate spacers 16, the contact etch stop features 21, and the ILD features 22 may also be partially removed in the photolithography process for forming the wall recesses 23. In some alternative embodiments, the gate spacers 16, the contact etch stop features 21, and the ILD features 22 may remain intact in the photolithography process.

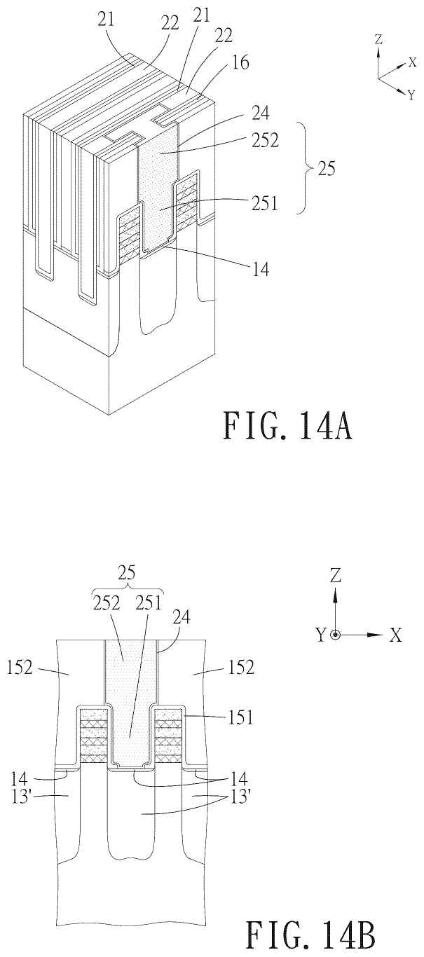

Referring to FIG. 1A and the example illustrated in FIGS. 14A and 14B, the method 100A then proceeds to step S11, where a plurality of liners 24 and a plurality of dielectric walls 25 are formed in the wall recesses 23, respectively. Each of the liners 24 covers a lateral surface and a bottom surface of a corresponding one of the dielectric walls 25. One of the liners 24 and one of the dielectric walls 25 are shown in FIGS. 14A and 14B. Step S11 may include sub-step (e1) sequentially forming a first dielectric material layer and a second dielectric material layer (not shown) on the structure shown in FIG. 13A or FIG. 13B by a suitable deposition process, for example, but not limited to, CVD (e.g., low-pressure CVD (LPCVD)), ALD, or other suitable deposition processes, so that the wall recesses 23 are filled with the first and the second dielectric material layers, and sub-step (e2) conducting a planarization process (e.g., the CMP process or other suitable planarization processes) to remove an excess portion of the first dielectric material layer and an excess portion of the second dielectric material layer, so as to form remaining portions of the first dielectric material layer into the liners 24 and to form remaining portions of the second dielectric material layer into the dielectric walls 25. In some embodiments, the first dielectric material layer (or the liners 24) and the second dielectric material layer (or the dielectric walls 25) may independently include silicon oxide, silicon nitride, silicon carbonitride, silicon oxycarbonitride, silicon oxycarbide, or combinations thereof. Other suitable materials for the first and second dielectric material layers are within the contemplated scope of the present disclosure. In some embodiments, the material for the first dielectric material layer (or the liners 24) may be different from that for the second dielectric material layer (or the dielectric walls 25). In some embodiments, the liners 24 and the dummy gate dielectrics 151 may be made of a same material (for example, but not limited to, silicon oxide), but have different etching selectivity. In some embodiments, each of the dielectric walls 25 may be divided into a lower wall portion 251 and an upper wall portion 252, where the lower wall portion 251 is disposed in the lower recess portion 231 (see FIG. 13B) of a corresponding one of the wall recesses 23, and the upper wall portion 252 is disposed in the upper recess portion 232 (see FIG. 13B) of the corresponding one of the wall recesses 23 and on the lower wall portion 251. In some alternative embodiments, the liners 24 may not be formed. In this case, the dielectric walls 25 are disposed to fully fill the wall recesses 23, respectively.

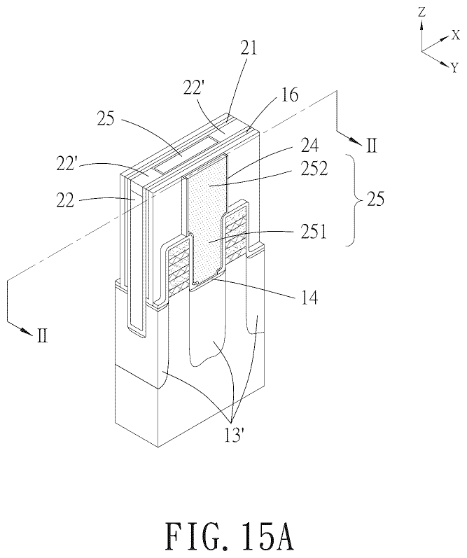

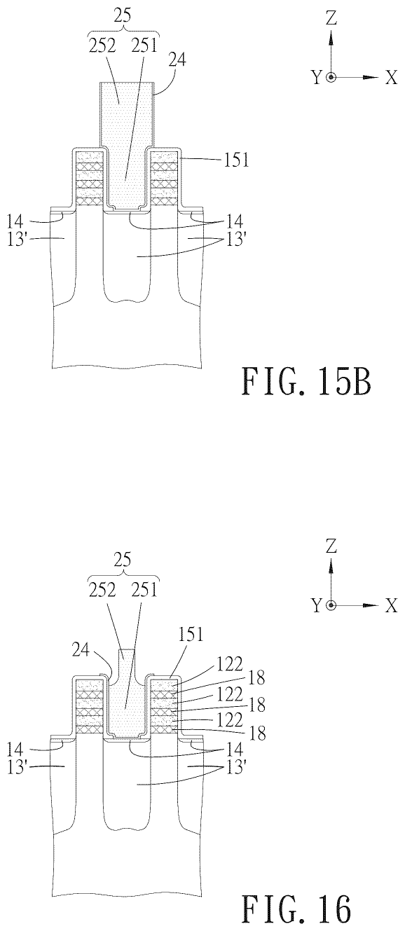

Referring to FIG. 1B and the example illustrated in FIGS. 15A and 15B, the method 100A then proceeds to step S12, where the dummy gate electrodes 152 are removed. FIG. 15B illustrates a cross-sectional view taken along line II-II of FIG. 15A. In some embodiments, the ILD features 22 of the structure shown in FIG. 14A are recessed by a suitable etching process (for example, but not limited to, a dry etching process, a wet etching process, other suitable etching processes, or combinations thereof) to form a plurality of recesses (not shown) on the ILD features 22. The recesses are then filled with a dielectric nitride-based material 22′ (for example, but not limited to, silicon nitride), and a planarization process (e.g., the CMP process or other suitable planarization processes) is performed to partially remove the dielectric nitride-based material 22′ to expose the dielectric walls 25. Thereafter, the dummy gate electrode 152 of the structure shown in FIG. 14A or FIG. 14B is removed by a suitable etching process, for example, but not limited to, a dry etching process, a wet etching process, other suitable etching processes, or combinations thereof.

Referring to FIG. 1B and the example illustrated in FIG. 16, the method 100A then proceeds to step S13, where the upper wall portion 252 of each of the dielectric walls 25 of the structure shown in FIG. 15B is laterally recessed. An upper portion of each of the liners 24 exposed from the dummy gate dielectric 151 and laterally covering the upper wall portion 252 of a corresponding one of the dielectric walls 25 is also removed when the upper wall portion 252 of each of the dielectric walls 25 is laterally recesses. Step S13 may be performed by a suitable etching process, such as a dry etching process. In this step, each of the materials for the dielectric walls 25 and the liners 24 have a high etching selectivity with respect to the materials for the dummy gate dielectric 151 and the gate spacers 16, in which the dielectric walls 25 are laterally covered by the gate spacers 16 in the Y direction (see FIG. 15A). That is, for a suitable kind of etchant, the dielectric walls 25 and the liners 24 can be readily etched, while the dummy gate dielectric 151 and the gate spacers 16 are left slightly etched or substantially intact.

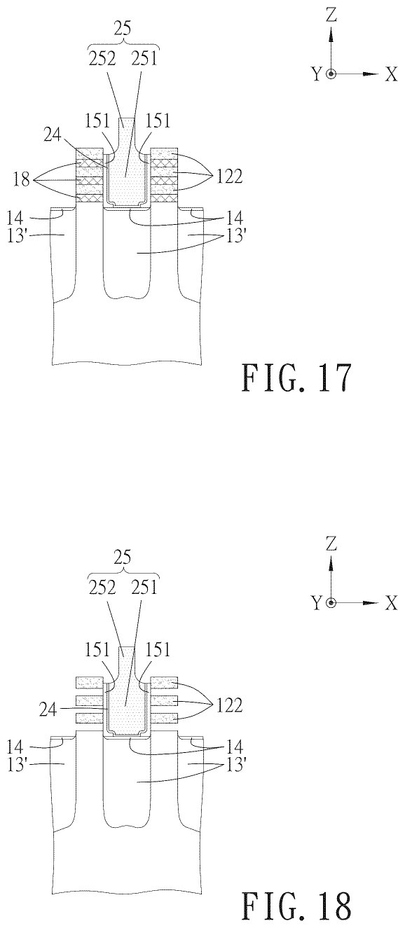

Referring to FIG. 1B and the example illustrated in FIG. 17, the method 100A then proceeds to step S14, where the dummy gate dielectric 151 is partially removed. Step S14 may be performed by a suitable etching process, such as a dry etching process. After this step, a remaining portion of the dummy gate dielectric 151 covers the lower wall portion 251 of each of the dielectric walls 25, and a remaining portion of each of the liners 24 is disposed between the remaining portion of the dummy gate dielectric 151 and the lower wall portion 251 of a corresponding one of the dielectric walls 25. In this step, the isolation layer portions 13′ covered by the mask portions 14 are not etched.

Referring to FIG. 1B and the example illustrated in FIG. 18, the method 100A then proceeds to step S15, where the interposers 18 of the structure shown in FIG. 17 are removed. Step S15 may be performed by a suitable etching process, for example, but not limited to, a dry etching process, a wet etching process, other suitable etching processes, or combinations thereof. Step S15 may be referred to as a sheet formation process (the channel features 122 resemble sheets). In this step, the isolation layer portions 13′ covered by the mask portions 14 are not etched.

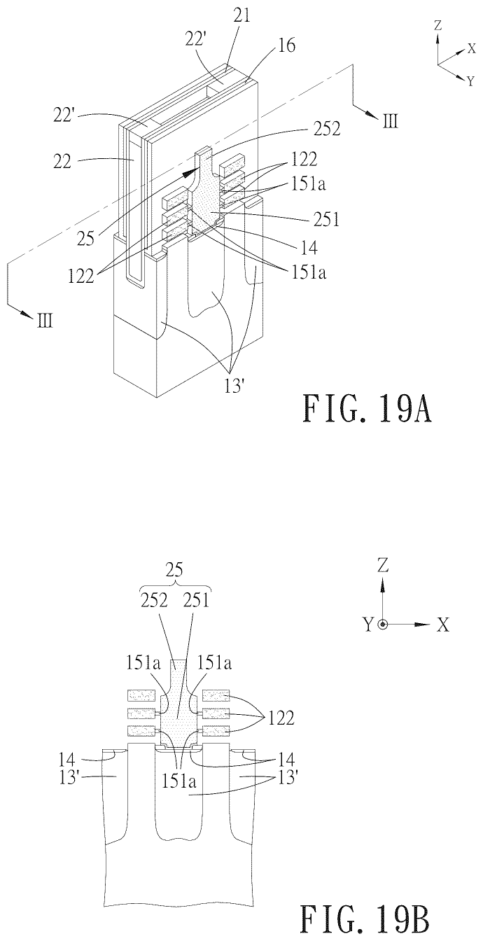

Referring to FIG. 1B and the example illustrated in FIGS. 19A and 19B, the method 100A then proceeds to step S16, where the remaining portion of the dummy gate dielectric 151 and the remaining portion of each of the liners 24 of the structure shown in FIG. 18 are partially removed to form a plurality of connecting elements 151a. FIG. 19B illustrates a cross-sectional view taken along line III-III of FIG. 19A. Each of the connecting elements 151a is disposed and connected between a corresponding one of the channel features 122 and the lower wall portion 251 of a corresponding one of the dielectric walls 25. Step S16 may be performed by a suitable etching process, for example, but not limited to, a dry etching process, a wet etching process, other suitable etching processes, or combinations thereof.

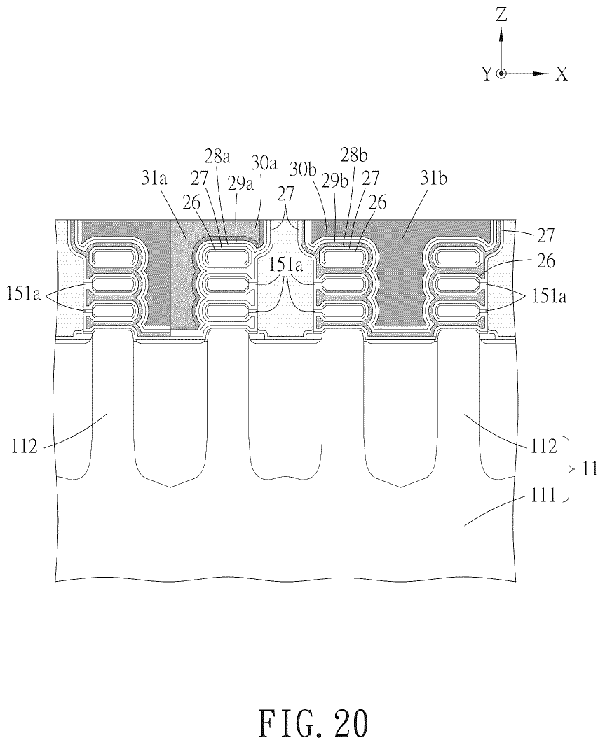

Referring to FIG. 1B and the example illustrated in FIG. 20, the method 100 then proceeds to step S17, where a plurality of interfacial layers 26, a high-k material layer 27, a first metal layer 28a, 28b, a second metal layer 29a, 29b, a third metal layer 30a, 30b, and a fourth metal layer 31a, 31b are sequentially formed on the structure shown in FIG. 19A or FIG. 19B. Step 116 may include sub-steps (f1), (f2), and (f3).

In sub-step (f1), a pre-clean process is conducted on the structure shown in FIG. 19A or 19B to oxidize the channel features 122, so as to form the interfacial layers 26 which cover the channel features 122 and top surfaces of the fin portions 112 of the semiconductor substrate 11, respectively. In some embodiments, the pre-clean process for forming the interfacial layers 26 may be conducted by one of RCA SC-1 (including ammonia, hydrogen peroxide and deionized water), RCA SC-2 (including hydrochloric acid, hydrogen peroxide and deionized water) and a combination thereof. Other suitable processes for forming the interfacial layers 26 are within the contemplated scope of the present disclosure. The interfacial layers 26 may include, for example, but not limited to, silicon oxide. Other suitable materials for the interfacial layers 26 are within the contemplated scope of the present disclosure.

In sub-step (f2), the high-k material layer 27, the first metal layer 28a, 28b, the second metal layer 29a, 29b, the third layer 30a, 30b, and the fourth metal layer 31a, 31b are sequentially formed on the interfacial layers 26 and other portions of the structure shown in FIG. 19A or FIG. 19B, which are not covered by the interfacial layers 26, by a suitable deposition process, for example, but not limited to, CVD, ALD, or other suitable deposition processes. In some embodiments, the high-k material layer 27 may include, for example, but not limited to, hafnium oxide, silicon nitride, silicon oxynitride, titanium oxide, hafnium zirconium oxide, tantalum oxide, hafnium silicon oxide, zirconium oxide, zirconium silicon oxide, lanthanum oxide, aluminum oxide, yttrium oxide, strontium titanate, barium titanate, barium zirconate, lanthanum silicon oxide, aluminum silicon oxide, hafnium lanthanum oxide, hafnium silicon oxide, aluminum silicon oxide, hafnium tantalum oxide, hafnium titanium oxide, other suitable high-k materials, or combinations thereof. The first metal layer 28a, 28b, the second metal layer 29a, 29b, the third metal layer 30a, 30b, and the fourth metal layer 31a, 31b may each be made of a work-function metallic material and may have different conductivity types. For example, the first metal layer 28a may be made of an n-type metal or an n-type metal compound, and the first metal layer 28b may be made of a p-type metal or a p-type metal compound. In some embodiments, the n-type metal may include, for example, but not limited to, titanium, aluminum, silver, manganese, zirconium, or other suitable n-type metals. In some embodiments, the n-type metal compound may include, for example, but not limited to, tantalum carbide, tantalum carbide nitride, tantalum silicon nitride, titanium silicon nitride, other suitable n-type metal compounds, or combinations thereof. In some embodiments, the p-type metal may include, for example, but not limited to, ruthenium, molybdenum, tungsten, platinum, or other suitable p-type metals. In some embodiments, the p-type metal compound may include, for example, but not limited to, titanium nitride, tantalum nitride, tungsten nitride, zirconium disilicide, molybdenum disilicide, tantalum disilicide, nickel disilicide, other p-type metal compounds, or combinations thereof. Other suitable materials for the first metal layer 28a, 28b, the second metal layer 29a, 29b, the third metal layer 30a, 30b, and the fourth metal layer 31a, 31b are within the contemplated scope of the present disclosure.

In sub-step (f3), a planarization process (e.g., the CMP process or other suitable planarization processes) is performed to partially remove the first metal layer 28a, 28b, the second metal layer 29a, 29b, the third metal layer 30a, 30b, and the fourth metal layer 31a, 31b, the high-k material layer 27, and the dielectric walls 25.

Referring to FIG. 1B and the example illustrated in FIGS. 21A and 21B, the method 100A then proceeds to step S18, where a plurality of isolation features 32 are formed. Step S18 may include sub-step (g1) conducting a photolithography process to pattern the structure shown in FIG. 20 so as to form a plurality of trenches (not shown), sub-step (g2) forming an isolation material layer (not shown) for the isolation features 32 on a top surface of a structure obtained after sub-step (g1) such that the isolation material layer fills the trenches, and sub-step (g3) conducting a planarization process (e.g., the CMP process or other suitable planarization processes) to remove an excess portion of the isolation material layer, so as to obtain the isolation features 32. In some embodiments, each of the isolation features 32 may penetrate the fourth metal layer 31a, 31b, the third metal layer 30a, 30b, the second metal layer 29a, 29b, the first metal layer 28a, 28b, the high-k material layer 27, and a corresponding one of the mask portions 14 and may extend into a corresponding one of the isolation layer portions 13′, so as to form the fourth metal layer 31a, 31b into a plurality of fourth metal portions 31a′, 31b′, to form the third metal layer 30a, 30 b into a plurality of third metal portions 30a′, 3b′, to form the second metal layer 29a, 29 b into a plurality of second metal portions 29a′, 29b′, and to form the first metal layer 28a, 28b into a plurality of first metal portions 28a′, 28b′ (see FIG. 21A). It is noted that each of the fourth metal portions 31a′, 31b′, a corresponding one of the third metal portions 30a′, 3b′, a corresponding one of the second metal portions 29a′, 29b′, and a corresponding one of the first metal portions 28a′, 28b′ may be collectively referred to as a metal gate portion.

In addition, each of the isolation features 32 is also disposed between corresponding two adjacent ones of the source/drain regions 20 (see FIG. 21B), so that the corresponding two adjacent ones of the source/drain regions 20 are isolated from each other by the each of the isolation features 32 in the X direction. The isolation material layer for the isolation features 32 may include, for example, but not limited to, silicon oxide, silicon nitride, silicon carbon nitride, silicon oxycarbonnitride, or other low-k materials. Other suitable materials for the isolation features 32 are within the contemplated scope of the present disclosure. In some embodiments, each of the dielectric walls 25 may be disposed between corresponding two adjacent ones of the isolation features 32 (see FIG. 21A).

After step S18, the semiconductor structure 200A is obtained. In some embodiments, the semiconductor structure 200A may be divided into a plurality of the semiconductor structures 41, 42, 43, 44 that are spaced apart from each other in the X direction. In some embodiments, the semiconductor structures 41, 43, 44 may be n-type metal-oxide-semiconductor field-effect transistors (NMOSFETs) and the semiconductor device 42 may be a p-type metal-oxide-semiconductor field-effect transistor (PMOSFET), and vice versa.

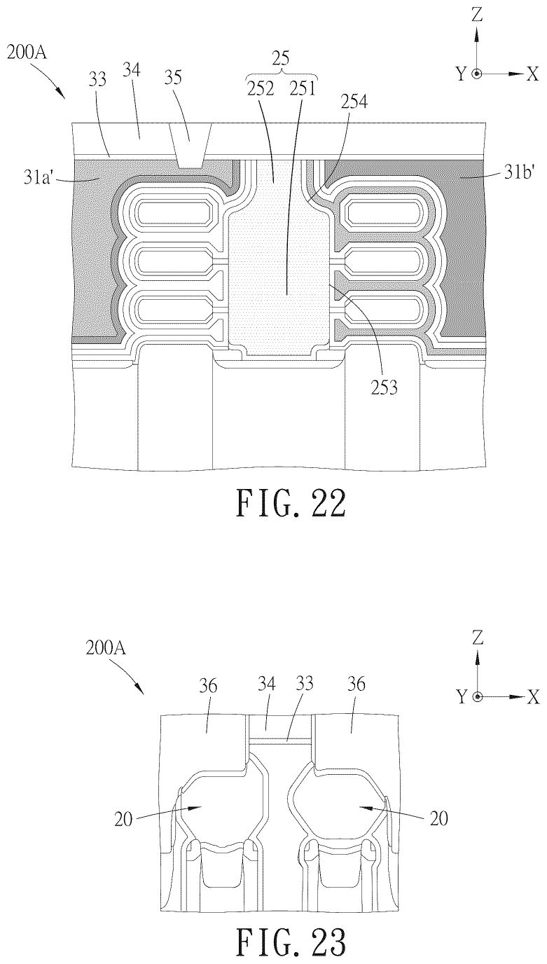

Referring to FIG. 1B and the examples illustrated in FIGS. 22 and 23, the method 100A may further proceeds to steps S19, S20, S21, S22.

In step S19, a contact etch stop layer 33 is formed on the structure shown in FIG. 21A or 21B. The process and the material for forming the contact etch stop layer 33 may be the same as or similar to those for the contact etch stop feature as described in step S09, and thus details thereof are omitted for the sake of brevity.

In step S20, a dielectric layer 34 is formed on the contact etch stop layer 33. In some embodiments, the dielectric layer 34 may include, for example, but not limited to, silicon oxide, silicon nitride, silicon carbide, silicon oxycarbide, silicon oxynitride, silicon carbonitride, silicon oxycarbonitride, other low-k dielectric materials, or combinations thereof. Other suitable materials for forming the dielectric layer 34 are within the contemplated scope of the present disclosure. In some embodiments, the dielectric layer 34 may be formed by a suitable deposition process, for example, but not limited to, CVD or ALD. Other suitable processes for forming the dielectric layer 34 are within the contemplated scope of the present disclosure.

In step S21, a metal contact 35 is formed to be connected to a corresponding one of the fourth metal portions 31a′, 31b′ (see FIG. 22). In some embodiments, the metal contact 35 may be formed by: (i) forming an opening (not shown), which penetrates the dielectric layer 34 and the contact etch stop layer 33 to expose the corresponding one of the fourth metal portions 31a′, 31b′, by an etching process; (ii) forming a conductive material layer (not shown) on the dielectric layer 34 to fill the opening; and (iii) conducting a planarization process (for example, but not limited to, the CMP) process) to remove a portion of the conducive material layer. In some embodiments, the etching process for forming the opening may be an anisotropic etching process, for example, but not limited to, an anisotropic dry etching process. In some embodiments, the metal contact 35 (or the conductive material layer) may include for example, but not limited to, cobalt, tungsten, ruthenium, molybdenum, copper, or combinations thereof. Other suitable conductive materials are within the contemplated scope of the present disclosure.

In step S21, at least one metal contact 36 is formed (see FIG. 23). Two metal contacts 36 are illustrated in FIG. 23, and each of the metal contacts 36 is connected to a corresponding one of the source/drain regions 20. The processes and the materials for forming the metal contacts 36 may be the same as or similar to those for forming the metal contact 35 as described in step S20, and thus details thereof are omitted for the sake of brevity.

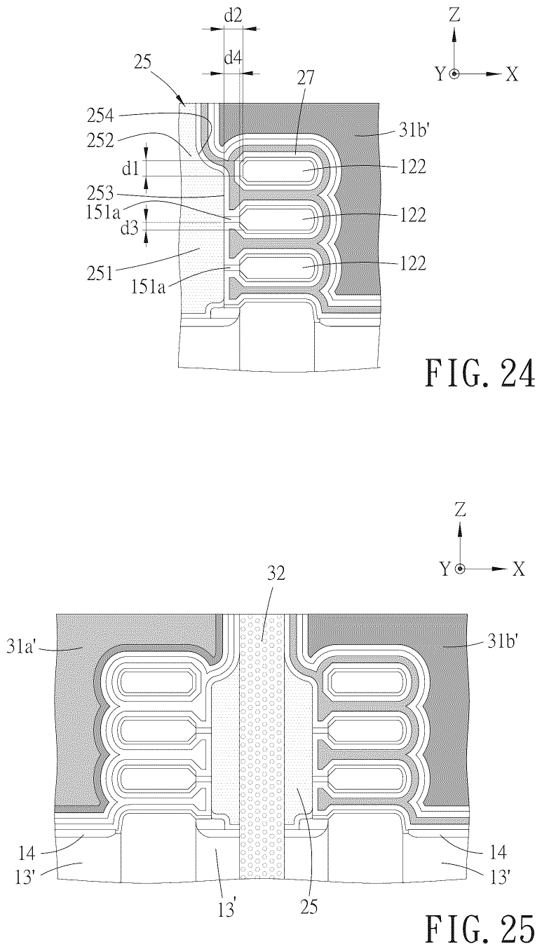

Referring to the example illustrated in FIG. 24, when a short-channel effect of a semiconductor device is reduced desirably, an AC penalty (a speed degradation) may be raised undesirably. Optimization of electrical characteristics (for example, but not limited to, control of the short-channel effect and relief of the AC penalty, and the like) of the semiconductor device may be achieved by controlling the parameters described below to be within desirable ranges. Referring to the examples illustrated in FIGS. 22 and 24, the upper wall portion 252 has an upper lateral surface 254 in a curved shape, and the lower wall portion 251 has a lower lateral surface 253 in a flat shape. The upper lateral surface 254 forms an interconnection region with the lower lateral surface 253. A distance (d1) between the interconnection region and an upper surface of an uppermost one of the channel features 122, which is fully surrounded by the high-k material layer 27, ranges from about 0 nm to about 10 nm. A distance (d2) between the lower wall portion 251 and the uppermost one of the channel features 122 ranges from about 3 nm to about 6 nm. When the distance (d2) is less than 3 nm, a gate control capability decreases and the short channel effect raises undesirably. When the distance (d2) is greater than 6 nm, the capacitance increases undesirably. A distance (d3) between a lower surface of each of the connecting elements 151a and a lower surface of a corresponding one of the channel features 122, which is connected to the each of the connecting elements 151a, ranges from about 0 nm to about 2 nm. When the distance (d3) is greater than 2 nm, the capacitance increases undesirably. A distance (d4) between the lower wall portion 251 and each of the channel features 122, which is connected to the lower wall portion 251 through a corresponding one of the connecting elements 151a, ranges from about 0 nm to about 5 nm. When the distance (d4) is greater than 5 nm, the capacitance increases undesirably.

Referring to the example illustrated in FIG. 25, in some alternative embodiments, an additional one of the isolation features 32 is formed to penetrate a corresponding one of the dielectric walls 25 and a corresponding one of the mask portions 14 and extends into a corresponding one of the isolation layer portions 13′, so as to enhance isolation between corresponding two adjacent ones of the metal gate portions.

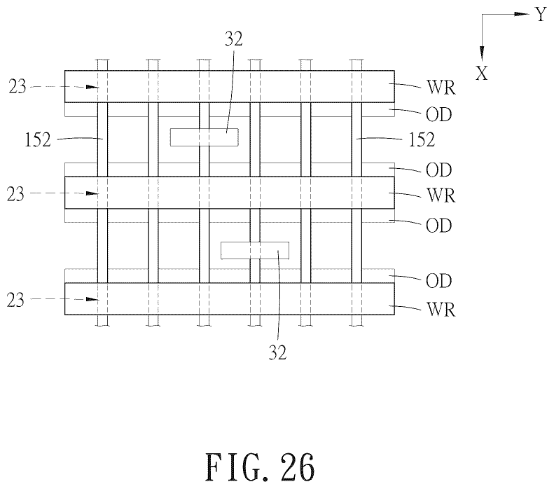

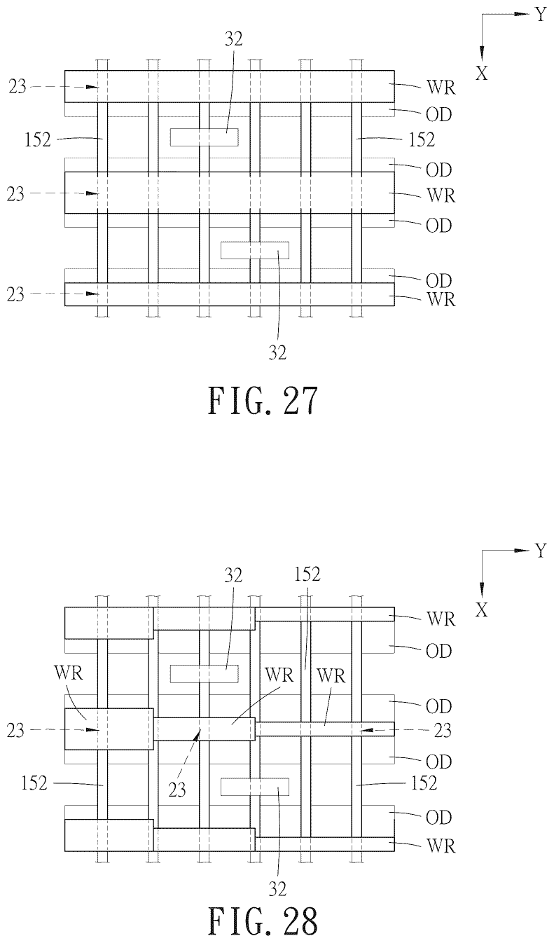

FIGS. 26 to 28 are layout diagrams, each of which illustrates a photomask pattern for forming the wall recesses 23, and a plurality of oxide-definition (OD) regions, at which the source/drain regions 20 (see FIG. 10) are formed. The wall recess (WR) definition region is formed between corresponding two adjacent ones of the oxide-definition (OD) regions. As shown in FIG. 26, in some embodiments, all of the wall recesses 23 may have a same dimension in the X direction, and all of the dielectric walls 25 thus formed have a same dimension in the X direction. As shown in FIG. 27, in some alternative embodiments, at least two of the wall recesses 23 formed in each of at least one of the dummy gate electrodes 152 may be dimensionally different from each other in the X direction, and at least two of the dielectric walls 25 thus formed in each of at least one of the metal gates may be dimensionally different from each other in the X direction. As shown in FIG. 28, in some further alternative embodiments, at least one of the wall recesses 23 formed in one of the dummy gate electrodes 152 may be dimensionally different from at least one of the wall recesses 23 formed on another one of the dummy gate electrodes 152 in the X direction, and at least one of the dielectric walls 25 thus formed in one of the metal gates may be dimensionally different from at least one of the dielectric walls 25 thus formed in another one of the metal gates in the X direction. In some embodiments, a dimensional difference of the dielectric walls 25 in the X direction may range from about 0 nm to about 15 nm.

In this disclosure, by forming at least one dielectric wall and at least one isolation feature in a semiconductor device, the semiconductor device may have an increased density of functional semiconductor structures (e.g., transistors), and each of the functional semiconductor structures may have a reduced capacitance and an improved power performance. The at least one dielectric wall and the at least one isolation feature may be spaced apart from each other in the semiconductor device, or the at least one isolation feature may penetrate through the at least one dielectric wall. In addition, the at least one dielectric wall is formed before the formation of the metal gate structure. Therefore, the size of the metal gate endcap portions can be reduced without affecting the threshold voltage (Vₜₕ) of the semiconductor device.

In accordance with some embodiments of the present disclosure, a method for manufacturing a semiconductor device includes: forming a plurality of first stacks on a semiconductor substrate in a first direction normal to the semiconductor substrate, the plurality of first stacks being spaced apart from each other in a second direction transverse to the first direction, each of the plurality of first stacks including a plurality of dielectric interposers and a plurality of channel features that are alternately stacked on the semiconductor substrate; forming a dummy poly gate on the semiconductor substrate, the dummy poly gate extending in the second direction and including a dummy gate dielectric covering the plurality of first stacks and a dummy gate electrode covering the dummy gate dielectric; removing a portion of the dummy gate electrode and a portion of the dummy gate dielectric, so as to form a wall recess between corresponding two immediate adjacent ones of the plurality of first stacks; forming a dielectric wall in the wall recess; removing remainder of the dummy gate electrode; removing the plurality of dielectric interposers; and forming a metal gate over the semiconductor substrate and the plurality of channel features, the metal gate including a plurality of metal gate portions, the dielectric wall being interconnected to corresponding two immediate adjacent ones of the plurality of metal gate portions.

In accordance with some embodiments of the present disclosure, the method for manufacturing a semiconductor device further includes: forming a plurality of second stacks on the semiconductor substrate in the first direction, the plurality of second stacks being spaced apart from each other in the second direction, each of the plurality of second stacks including a plurality of sacrificial features and the plurality of channel features that are alternately stacked on the semiconductor substrate, the plurality of sacrificial features including a semiconductor material; and replacing the plurality of sacrificial features with the plurality of dielectric interposers, respectively, so as to convert the plurality of second stacks to the plurality of first stacks.

In accordance with some embodiments of the present disclosure, the method for manufacturing a semiconductor device further includes laterally recessing an upper wall portion of the dielectric wall.

In accordance with some embodiments of the present disclosure, the method for manufacturing a semiconductor device further includes, before removal of the remainder of the dummy gate electrode, forming a liner in the wall recess to cover a lateral surface and a bottom surface of the dielectric wall.

In accordance with some embodiments of the present disclosure, the method for manufacturing a semiconductor device further includes, after the upper wall portion of the dielectric wall is laterally recessed, partially removing the dummy gate dielectric, so that remainder of the dummy gate dielectric covers a lower wall portion of the dielectric wall and so that remainder of the liner is disposed between the remainder of the dummy gate dielectric and the lower wall portion of the dielectric wall.

In accordance with some embodiments of the present disclosure, the method for manufacturing a semiconductor device further includes, after the dielectric interposers are removed, partially removing the remainder of the dummy gate dielectric and the remainder of the liner to form a plurality of connecting elements, each of which is disposed and connected between a corresponding one of the channel features and the lower wall portion of the dielectric wall.

In accordance with some embodiments of the present disclosure, the semiconductor substrate includes a plurality of fin portions spaced apart from one another in the second direction. The method for manufacturing a semiconductor device further includes, before formation of the plurality of second stacks: forming a plurality of isolation layer portions so that two intermediate adjacent ones of the plurality of fin portions are isolated from each other by a corresponding one of the plurality of isolation layer portions, and forming a plurality of mask portions on the plurality of isolation layer portions, respectively, so that the dummy gate dielectric is formed on the plurality of mask portions after formation of the dummy poly gate.

In accordance with some embodiments of the present disclosure, the wall recess is formed to expose a corresponding one of the plurality of mask portions through the wall recess.

In accordance with some embodiments of the present disclosure, the method for manufacturing a semiconductor device further includes, before removal of the remainder of the dummy gate electrode, forming a liner in the wall recess to cover a lateral surface and a bottom surface of the dielectric wall, so that the liner is in contact with a corresponding one of the plurality of mask portions.

In accordance with some embodiments of the present disclosure, the method for manufacturing a semiconductor device further includes, forming an isolation feature between corresponding two immediate adjacent ones of the plurality of metal gate portions, the isolation feature being spaced apart from the dielectric wall by a corresponding one of the metal gate portions.

In accordance with some embodiments of the present disclosure, the method for manufacturing a semiconductor device further includes, forming an isolation feature penetrating the dielectric wall in the first direction.

In accordance with some embodiments of the present disclosure, a method for manufacturing a semiconductor device includes: forming a plurality of first stacks on a semiconductor substrate in a first direction normal to the semiconductor substrate, the plurality of first stacks being spaced apart from each other in a second direction transverse to the first direction, each of the plurality of first stacks including a plurality of first dielectric interposers and a plurality of first channel features that are alternately stacked on the semiconductor substrate; forming a first dummy poly gate on the semiconductor substrate, the first dummy poly gate extending in the second direction and including a first dummy gate dielectric covering the plurality of first stacks and a first dummy gate electrode covering the first dummy gate dielectric; removing a plurality of portions of the first dummy gate electrode and a plurality of portions of the first dummy gate dielectric, so as to form a plurality of first wall recesses, each of which is formed between corresponding two immediate adjacent ones of the plurality of first stacks; forming a plurality of first liners and a plurality of first dielectric walls in the plurality of first wall recesses, respectively, each of the plurality of first dielectric walls being interconnected to the corresponding two immediate adjacent ones of the plurality of first stacks through the dummy gate dielectric and a corresponding one of the plurality of first liners; removing remainder of the first dummy gate electrode; removing an upper portion of each of the plurality of first liners and laterally recessing an upper wall portion of each of the plurality of first dielectric walls; removing the plurality of first dielectric interposers; and forming a first metal gate over the semiconductor substrate and the plurality of first channel features, the first metal gate including a plurality of first metal gate portions, each of the plurality of first dielectric walls being interconnected to corresponding two immediate adjacent ones of the plurality of first metal gate portions.

In accordance with some embodiments of the present disclosure, at least two of the plurality of first wall recesses are dimensionally different from each other in the second direction, and at least two of the plurality of first dielectric walls are dimensionally different from each other in the second direction.

In accordance with some embodiments of the present disclosure, the method for manufacturing a semiconductor device further includes: forming a plurality of second stacks on the semiconductor substrate in the first direction, the plurality of second stacks being spaced apart from each other in the second direction and being spaced apart from the plurality of first stacks in a third direction transverse to the first direction and the second direction, each of the plurality of second stacks including a plurality of second dielectric interposers and a plurality of second channel features that are alternately stacked on the semiconductor substrate; forming a second dummy poly gate on the semiconductor substrate, the second dummy poly gate extending in the second direction and being spaced apart from the first dummy poly gate in the third direction, the second dummy poly gate including a second dummy gate dielectric covering the plurality of second stacks and a second dummy gate electrode covering the second dummy gate dielectric; removing a plurality of portions of the second dummy gate electrode and a plurality of portions of the dummy gate dielectric, so as to form a plurality of second wall recesses, each of which being formed between corresponding two immediate adjacent ones of the plurality of second stacks; forming a plurality of second liners and a plurality of second dielectric walls in the plurality of second wall recesses, respectively; removing remainder of the second dummy gate electrode; removing an upper portion of each of the plurality of second liners and laterally recessing an upper wall portion of each of the second dielectric walls; removing the plurality of second dielectric interposers; and forming a second metal gate over the semiconductor substrate and the plurality of second channel features, the second metal gate including a plurality of second metal gate portions, each of the second dielectric walls being interconnected to corresponding two immediate adjacent ones of the plurality of second metal gate portions.

In accordance with some embodiments of the present disclosure, at least one of the plurality of first wall recesses is dimensionally different from at least one of the plurality of second wall recesses in the second direction, and at least one of the plurality of first dielectric walls is dimensionally different from at least one of the plurality of second dielectric walls in the second direction.

In accordance with some embodiments of the present disclosure, a semiconductor device includes a semiconductor substrate, a first semiconductor structure and a second semiconductor structure disposed on the semiconductor substrate, a dielectric wall, and a plurality of connecting elements. Each of the first semiconductor structure and the second semiconductor structure includes a plurality of channel features and a metal gate portion. The plurality of channel features are spaced apart from each other in a first direction normal to the semiconductor substrate, and include an uppermost channel feature and remaining channel features disposed below the uppermost channel feature. The metal gate portion is disposed over the semiconductor substrate and the plurality of channel features. The dielectric wall is interconnected to the metal gate portion of the first semiconductor structure and the metal gate portion of the second semiconductor structure, and includes a lower wall portion and an upper wall portion disposed on the lower wall portion. Each of the plurality of connecting elements is interconnected to a corresponding one of the remaining channel features and the lower wall portion.

In accordance with some embodiments of the present disclosure, the upper wall portion has an upper lateral surface in a curved shape, the lower wall portion has a lower lateral surface in a flat shape, the upper lateral surface forms an interconnection region with the lower lateral surface, and a distance between the interconnection region and an upper surface of the uppermost channel feature ranges from about 0 nm to about 10 nm.

In accordance with some embodiments of the present disclosure, a distance between the lower wall portion and the uppermost channel feature ranges from about 3 nm to about 6 nm.

In accordance with some embodiments of the present disclosure, a distance between a lower surface of each of the connecting elements and a lower surface of a corresponding one of the remaining channel features, which is connected to the each of the connecting elements, ranges from about 0 nm to about 2 nm.

In accordance with some embodiments of the present disclosure, a distance between the lower wall portion and each of the remaining channel features ranges from about 0 nm to about 5 nm.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a plurality of first stacks on a semiconductor substrate in a first direction normal to the semiconductor substrate, the plurality of first stacks being spaced apart from each other in a second direction transverse to the first direction, each of the plurality of first stacks including a plurality of dielectric interposers and a plurality of channel features that are alternately stacked on the semiconductor substrate;
forming a dummy poly gate on the semiconductor substrate, the dummy poly gate extending in the second direction and including a dummy gate dielectric covering the plurality of first stacks and a dummy gate electrode covering the dummy gate dielectric;
removing a portion of the dummy gate electrode and a portion of the dummy gate dielectric, so as to form a wall recess between corresponding two immediate adjacent ones of the plurality of first stacks;
forming a dielectric wall in the wall recess;
removing remainder of the dummy gate electrode;
removing the plurality of dielectric interposers; and
forming a metal gate over the semiconductor substrate and the plurality of channel features, the metal gate including a plurality of metal gate portions, the dielectric wall being interconnected to corresponding two immediate adjacent ones of the plurality of metal gate portions.

2. The method as claimed in claim 1, further comprising:
forming a plurality of second stacks on the semiconductor substrate in the first direction, the plurality of second stacks being spaced apart from each other in the second direction, each of the plurality of second stacks including a plurality of sacrificial features and the plurality of channel features that are alternately stacked on the semiconductor substrate, the plurality of sacrificial features including a semiconductor material; and
replacing the plurality of sacrificial features with the plurality of dielectric interposers, respectively, so as to convert the plurality of second stacks to the plurality of first stacks.

3. The method as claimed in claim 1, further comprising laterally recessing an upper wall portion of the dielectric wall.

4. The method as claimed in claim 3, further comprising, before removal of the remainder of the dummy gate electrode, forming a liner in the wall recess to cover a lateral surface and a bottom surface of the dielectric wall.

5. The method as claimed in claim 4, further comprising, after the upper wall portion of the dielectric wall is laterally recessed, partially removing the dummy gate dielectric, so that remainder of the dummy gate dielectric covers a lower wall portion of the dielectric wall and so that remainder of the liner is disposed between the remainder of the dummy gate dielectric and the lower wall portion of the dielectric wall.

6. The method as claimed in claim 5, further comprising, after the dielectric interposers are removed, partially removing the remainder of the dummy gate dielectric and the remainder of the liner to form a plurality of connecting elements, each of which is disposed between a corresponding one of the channel features and the lower wall portion of the dielectric wall.

7. The method as claimed in claim 2, wherein
the semiconductor substrate includes a plurality of fin portions spaced apart from one another in the second direction;
the method further comprises, before formation of the plurality of second stacks:
forming a plurality of isolation layer portions so that two intermediate adjacent ones of the plurality of fin portions are isolated from each other by a corresponding one of the plurality of isolation layer portions, and
forming a plurality of mask portions on the plurality of isolation layer portions, respectively, so that the dummy gate dielectric is formed on the plurality of mask portions after formation of the dummy poly gate.

8. The method as claimed in claim 7, wherein the wall recess is formed to expose a corresponding one of the plurality of mask portions through the wall recess.

9. The method as claimed in claim 7, further comprising, before removal of the remainder of the dummy gate electrode, forming a liner in the wall recess to cover a lateral surface and a bottom surface of the dielectric wall, so that the liner is in contact with a corresponding one of the plurality of mask portions.

10. The method as claimed in claim 1, further comprising:
forming an isolation feature between corresponding two immediate adjacent ones of the plurality of metal gate portions, the isolation feature being spaced apart from the dielectric wall by a corresponding one of the metal gate portions.

11. The method as claimed in claim 1, further comprising:
forming an isolation feature penetrating the dielectric wall in the first direction.

12. A method for manufacturing a semiconductor device, comprising:
forming a plurality of first stacks on a semiconductor substrate in a first direction normal to the semiconductor substrate, the plurality of first stacks being spaced apart from each other in a second direction transverse to the first direction, each of the plurality of first stacks including a plurality of first dielectric interposers and a plurality of first channel features that are alternately stacked on the semiconductor substrate;
forming a first dummy poly gate on the semiconductor substrate, the first dummy poly gate extending in the second direction and including a first dummy gate dielectric covering the plurality of first stacks and a first dummy gate electrode covering the first dummy gate dielectric;
removing a plurality of portions of the first dummy gate electrode and a plurality of portions of the first dummy gate dielectric, so as to form a plurality of first wall recesses, each of which is formed between corresponding two immediate adjacent ones of the plurality of first stacks;
forming a plurality of first liners and a plurality of first dielectric walls in the plurality of first wall recesses, respectively, each of the plurality of first dielectric walls being interconnected to the corresponding two immediate adjacent ones of the plurality of first stacks through the dummy gate dielectric and a corresponding one of the plurality of first liners;
removing remainder of the first dummy gate electrode;
removing an upper portion of each of the plurality of first liners and laterally recessing an upper wall portion of each of the plurality of first dielectric walls;
removing the plurality of first dielectric interposers; and
forming a first metal gate over the semiconductor substrate and the plurality of first channel features, the first metal gate including a plurality of first metal gate portions, each of the plurality of first dielectric walls being interconnected to corresponding two immediate adjacent ones of the plurality of first metal gate portions.

13. The method as claimed in claim 12, wherein at least two of the plurality of first wall recesses are dimensionally different from each other in the second direction, and at least two of the plurality of first dielectric walls are dimensionally different from each other in the second direction.

14. The method as claimed in claim 12, further comprising:
forming a plurality of second stacks on the semiconductor substrate in the first direction, the plurality of second stacks being spaced apart from each other in the second direction and being spaced apart from the plurality of first stacks in a third direction transverse to the first direction and the second direction, each of the plurality of second stacks including a plurality of second dielectric interposers and a plurality of second channel features that are alternately stacked on the semiconductor substrate;
forming a second dummy poly gate on the semiconductor substrate, the second dummy poly gate extending in the second direction and being spaced apart from the first dummy poly gate in the third direction, the second dummy poly gate including a second dummy gate dielectric covering the plurality of second stacks and a second dummy gate electrode covering the second dummy gate dielectric;
removing a plurality of portions of the second dummy gate electrode and a plurality of portions of the dummy gate dielectric, so as to form a plurality of second wall recesses, each of which being formed between corresponding two immediate adjacent ones of the plurality of second stacks;
forming a plurality of second liners and a plurality of second dielectric walls in the plurality of second wall recesses, respectively;
removing remainder of the second dummy gate electrode;
removing an upper portion of each of the plurality of second liners and laterally recessing an upper wall portion of each of the second dielectric walls;
removing the plurality of second dielectric interposers; and
forming a second metal gate over the semiconductor substrate and the plurality of second channel features, the second metal gate including a plurality of second metal gate portions, each of the second dielectric walls being interconnected to corresponding two immediate adjacent ones of the plurality of second metal gate portions.

15. The method as claimed in claim 14, wherein at least one of the plurality of first wall recesses is dimensionally different from at least one of the plurality of second wall recesses in the second direction, and at least one of the plurality of first dielectric walls is dimensionally different from at least one of the plurality of second dielectric walls in the second direction.

16. A semiconductor device, comprising:
a semiconductor substrate;
a first semiconductor structure and a second semiconductor structure disposed on the semiconductor substrate, each of the first semiconductor structure and the second semiconductor structure including:
a plurality of channel features spaced apart from each other in a first direction normal to the semiconductor substrate, and including an uppermost channel feature and remaining channel features disposed below the uppermost channel feature, and
a metal gate portion disposed over the semiconductor substrate and the plurality of channel features;
a dielectric wall interconnected to the metal gate portion of the first semiconductor structure and the metal gate portion of the second semiconductor structure, and including a lower wall portion and an upper wall portion disposed on the lower wall portion; and
a plurality of connecting elements, each of which is interconnected to a corresponding one of the remaining channel features and the lower wall portion.

17. The semiconductor device as claimed in claim 16, wherein the upper wall portion has an upper lateral surface in a curved shape, the lower wall portion has a lower lateral surface in a flat shape, the upper lateral surface forms an interconnection region with the lower lateral surface, and a distance between the interconnection region and an upper surface of the uppermost channel feature ranges from 0 nm to 10 nm.

18. The semiconductor device as claimed in claim 16, wherein a distance between the lower wall portion and the uppermost channel feature ranges from 3 nm to 6 nm.

19. The semiconductor device as claimed in claim 16, wherein a distance between a lower surface of each of the connecting elements and a lower surface of a corresponding one of the remaining channel features, which is connected to the each of the connecting elements, ranges from 0 nm to 2 nm.

20. The semiconductor device as claimed in claim 16, wherein a distance between the lower wall portion and each of the remaining channel features ranges from 0 nm to 5 nm.
